(19) United States
(12) Patent Application Publication
(10) Pub. No.: US 2005/0151166 A1
(43) Pub. Date: Jul. 14, 2005

(54) Metal contact structure and method of manufacture

(76) Inventors: Chun-Chieh Lin, Hsin-Chu (TW); Chih-Hsin Ko, Kaohsiung (TW); Wen-Chin Lee, Hsin-Chu (TW)

Correspondence Address: SLATER & MATSIL, L.L.P., 17950 PRESTON RD, SUITE 1000, DALLAS, TX, 75252-5793, US

(21) Appl. No.: 10/835,100

(22) Filed: Apr. 29, 2004

Related U.S. Application Data
(60) Provisional application No. 60/535,303, filed on Jan. 9, 2004.

(51) Int. Cl. H01L 27/10

(52) U.S. Cl. 257/204

(57) ABSTRACT

A semiconductor device having a metal contact is provided. In the preferred embodiment, a metal contact is provided through an interlayer dielectric and is in electrical contact with a metal structure, such as a metal gate electrode of a transistor. A conductive layer is provided between the metal contact and the metal structure. The conductive layer provides one or more of a barrier layer, an adhesion layer, or an etch stop layer. The conductive layer is preferably an elemental metal, metal alloy, metal nitride, metal oxide, or a combination thereof. In an alternative embodiment, the conductive layer is formed of polysilicon.

This application claims the benefit of U.S. Provisional Application No. 60/535,303 filed on Jan. 9, 2004, entitled Metal Contact Structure and Method of Manufacture, which application is hereby incorporated herein by reference.

### TECHNICAL FIELD

The present invention relates generally to semiconductor devices, and more particularly to a metal contact structure for use in semiconductor devices.

### BACKGROUND

Complementary metal-oxide-semiconductor (CMOS) technology is the dominant semiconductor technology used for the manufacture of ultra-large scale integrated (ULSI) circuits today. Current CMOS transistors typically utilize polysilicon as the gate electrode for both NMOS and PMOS transistors, wherein the polysilicon is doped with an N-type dopant to form NMOS transistors and is doped with a P-type dopant to form PMOS transistors.

An interlayer dielectric is typically formed over the CMOS transistors, and contact plugs are formed through the interlayer dielectric to the polysilicon gate electrode. The contact plugs are typically filled with a metal, such as copper or tungsten. To improve the contact between the metal and the polysilicon, the surface of the polysilicon is frequently silicided.

Polysilicon gates, however, often exhibit gate depletion problems and are difficult to optimize the threshold voltage. Furthermore, the amount that a polysilicon gate may be doped is limited, thereby limiting the effect of doping on the threshold voltage. This restricts the amount the feature size of polysilicon structures, such as polysilicon gates, may be reduced.

In an attempt to solve these problems, attempts have been made to utilize metal gates. The metal gates generally allow smaller channel designs and allows for the optimization of the threshold voltage by, for example, utilizing different metals having different operating characteristics.

The operating characteristics, particularly the work function, of metal gates, however, may be altered by interlayer metal contacts. When the work function of the metal gates is altered, it is difficult to design circuitry that operates in a known and predictable manner. This problem becomes more troublesome in smaller designs, such as 65 nm and below designs, in which changes in the work function have a dramatic effect on the operation of the devices.

Therefore, there is a need for a metal contact structure such that the work function of the gate electrode is substantially retained.

### SUMMARY OF THE INVENTION

These and other problems are generally reduced, solved or circumvented, and technical advantages are generally achieved, by embodiments of the present invention, which provides a metal-to-metal contact structure for use in semiconductor devices.

In one embodiment of the present invention, a contact structure is formed through an interlayer dielectric to a metal structure formed on a substrate. The metal structure may be, for example, a metal gate electrode of a transistor or an intermediate metal layer contact pad. The contact structure preferably comprises a conductive layer positioned between a metal contact and the metal structure. In one embodiment, the conductive layer may be, for example, an elemental metal, metal alloy, metal silicide, metal nitride, metal oxide, or a combination thereof. In an alternative embodiment, the conductive layer is formed of polysilicon.

In a first embodiment, a metal structure, such as a metal gate electrode, is formed in accordance with known processing techniques. An interlayer dielectric layer is formed over the metal structure, and a contact hole is formed through the interlayer dielectric above the metal structure. A conductive layer is formed in the contact hole, and the contact hole is filled with a conductive material. In one embodiment, the conductive layer may be, for example, an elemental metal, metal alloy, metal silicide, metal nitride, metal oxide, or a combination thereof. In an alternative embodiment, the conductive layer is formed of polysilicon.

In a second embodiment, a metal structure, such as a metal gate electrode, is formed in accordance with known processing techniques. A conductive layer is formed and patterned over at least a portion of the metal structure. An interlayer dielectric layer is formed over the metal structure, and a contact hole is formed through the interlayer dielectric above the metal structure. The contact hole is filled with a conductive material. In one embodiment, the conductive layer may be, for example, an elemental metal, metal alloy, metal silicide, metal nitride, metal oxide, or a combination thereof. In an alternative embodiment, the conductive layer is formed of polysilicon.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a-1e are cross-section views of a wafer illustrating a process of forming a metal contact structure in accordance with a first embodiment of the present invention; and

FIGS. 2a-2f cross-section views of a wafer illustrating a process of forming a metal contact structure in accordance with a second embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. In particular, the method of the present invention is described in the context of forming a metal-to-metal contact between a metal gate structure of a transistor and a metal contact. One of ordinary skill in the art, however, will appreciate that the process described herein may be used for forming any type of device or structure that may use metal-to-metal contacts. Accordingly, the specific embodiments discussed herein are merely illustrative of specific ways to make and use the invention, and do not limit the scope of the invention.

The embodiments described herein are particularly useful in 65 nm designs and smaller. As noted above, metal gates allow smaller channels due to the ability to control the threshold voltage to a greater degree. In order to take full advantage of this feature, however, it is necessary to form a good conductive connection to the contacts and to limit the inter-diffusion rate between the metal gate and contact, which is typically metal. Accordingly, the present invention provides a conductive layer between a metal gate and a metal contact. The conductive layer may be, for example, an elemental metal, metal alloy, metal nitride, metal oxide, polysilicon, a combination thereof, or the like. In the preferred embodiment, the conductive layer is selected such that the conductive layer provides an adhesion layer to provide a better contact between the metal gate and the metal contact, and provides a barrier layer to limit the inter-diffusion rate between the metal gate and the metal contact. Furthermore, in some embodiments it is desirable to select a material that provides an etch stop layer during fabrication.

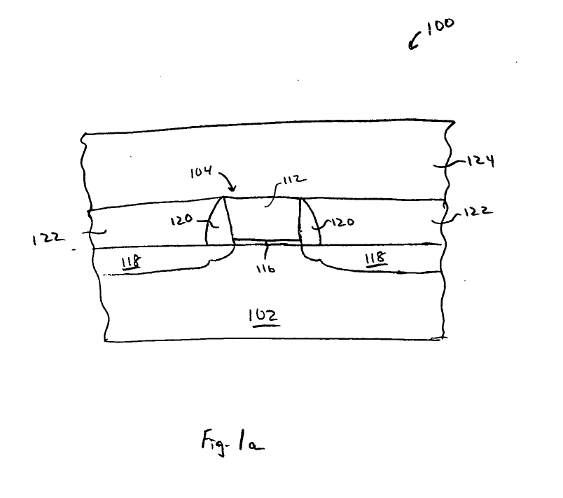

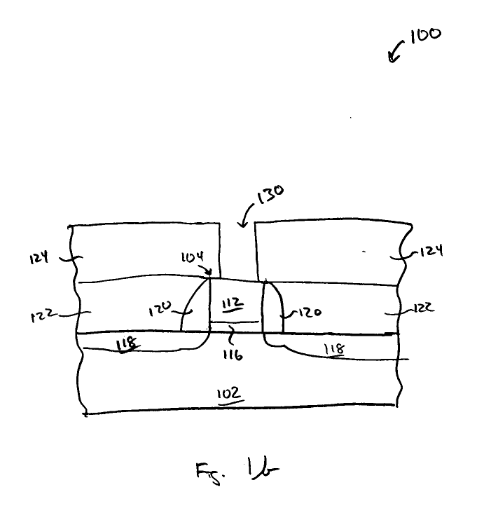

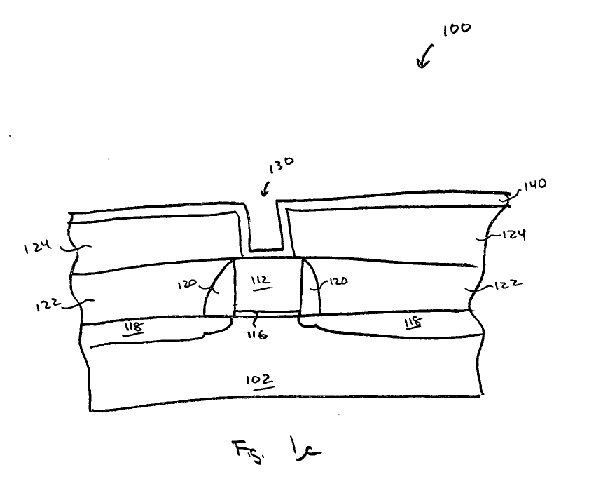

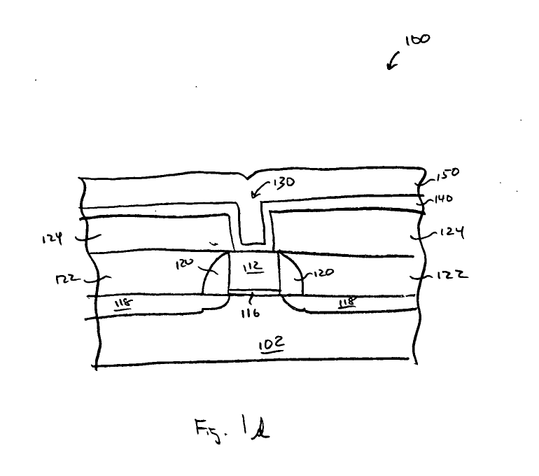

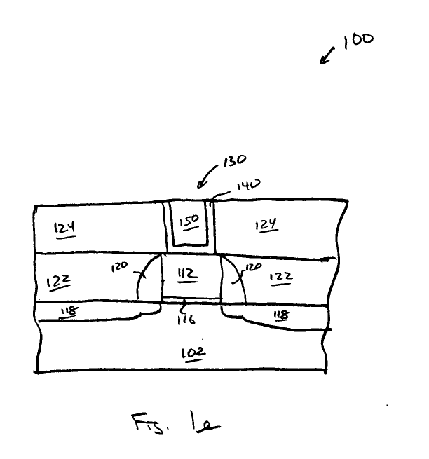

FIGS. 1a-1e illustrate cross-section views of a portion of a semiconductor wafer 100 during various steps of a first method embodiment of the present invention. The process begins in FIG. 1a, wherein a semiconductor wafer 100 having a substrate 102 with a transistor 104 formed thereon. The substrate 102 is preferably a silicon substrate, which is typically undoped, but may be lightly doped. Other materials, such as germanium, silicon germanium, graded silicon germanium, semiconductor-on-insulator, carbon, quartz, sapphire, and glass, oxide could alternatively be used for the substrate 102.

Transistor 104 includes a metal gate electrode 112, source/drain regions 118, and a gate dielectric layer 116 formed between the gate electrode 112 and the substrate 102. Spacers 120 are formed along the side of the gate electrodes 112. A first interlayer dielectric (ILD) layer 122 may be added to fill the gaps between devices and to allow a substantially planar surface. The planar surface of the first ILD layer 122 is frequently formed by a chemical mechanical polishing (CMP) wherein the gate electrode 112 acts as a stop layer. The structure shown in FIG. 1a may be formed by standard processes known in the art and may comprise either NMOS structures, PMOS structures, or a combination thereof.

The gate dielectric 116 is preferably a high-K dielectric material, a silicon-containing material, an oxygen-containing material, a nitrogen-containing material, or the like. The gate dielectric 116 may also be formed of a transition metal oxide having a dielectric constant less than or equal to about 50. The EOT of the gate dielectric 116 is preferably less than or equal to about 50 Å.

The gate electrode 112 may comprise one or more layers, e.g., a dual metal layer gate electrode, formed from an elemental metal, metal alloy, metal nitride, metal oxide, a combination thereof, or the like. Suitable materials include titanium, titanium nitride, molybdenum, tantalum, aluminum, tantalum nitride, ruthenium, niobium, zirconium, tungsten, nickel, molybdenum nitride, cobalt, ruthenium oxide, magnesium, platinum, copper, erbium, silver, palladium, iridium, or a combination thereof. More preferably, however, the gate electrode 112 comprises zirconium, erbium, aluminum, a combination thereof, or the like, and is less than or equal to about 100 Å in thickness.

A second ILD layer 124 is deposited over the first ILD layer 122 and the gate electrode 112. The first ILD layer 122 and the second ILD layer 124 typically comprise silicon oxide formed, for example, by deposition techniques such as chemical vapor deposition (CVD).

FIG. 1b illustrates wafer 100 of FIG. 1a after a contact hole 130 has been formed in the second ILD layer 124. The contact hole 130 provides a contact between metal lines (not shown) formed on the second ILD layer 124 and subsequent ILD layers (not shown). The second ILD layer 124 is preferably patterned by photolithography techniques as is known in the art. Generally, photolithography techniques involves depositing a photoresist material, which is masked, exposed, and developed to expose portions of the second ILD layer 124. The remaining photoresist material protects the underlying material from subsequent processing steps, such as etching. In the preferred embodiment, photoresist material is utilized to create a patterned mask to define contact hole 130. The etching process may be an anisotropic or isotropic, etch process, but preferably is an anisotropic dry etch process.

FIG. 1c illustrates wafer 100 of FIG. 1b after a first conductive layer 140 has been formed. The first conductive layer 140 is preferably formed from an elemental metal, metal alloy, metal silicide, metal nitride, metal oxide, a combination thereof, or the like. Suitable materials include titanium, titanium nitride, molybdenum, tantalum, aluminum, tantalum nitride, ruthenium, niobium, zirconium, tungsten, nickel, molybdenum nitride, cobalt, ruthenium oxide, magnesium, platinum, copper, erbium, silver, palladium, iridium, or a combination thereof. Furthermore, the first conductive layer 140 is preferably not the same type of metal as the gate electrode 112. In this manner, the first conductive layer 140 may be selected such that the first conductive layer 140 may act as an adhesion layer between the gate electrode 112 and a second metal layer 150, which is discussed below with reference to FIG. 1d. In the preferred embodiment in which the gate electrode 112 is formed of zirconium, erbium, aluminum, a combination thereof, or the like, the first conductive layer 140 comprises titanium nitride, tantalum nitride, or the like.

The first conductive layer 140 may be formed, for example, by sputtering or CVD. Preferably, the first metal layer 140 is 50-100 Å, but more preferably about 100 Å.

In an alternative embodiment, the first conductive layer 140 may comprise a semiconductor material such as polysilicon, amorphous silicon, or the like, but preferably polysilicon. The polysilicon may be deposited doped or undoped. For example, the first conductive layer 140 may be formed by depositing undoped polysilicon by low-pressure chemical vapor deposition (LPCVD). The polysilicon may be doped with other n-type dopants, such as nitrogen, phosphorous, arsenic, antimony, or the like, or other p-type dopants, such as boron, aluminum, gallium, indium, or the like. The polysilicon may also be deposited, for example, by furnace deposition of an in-situ doped polysilicon.

In this alternative embodiment, it is preferred that the thickness of the first conductive layer 140 is such that the ratio of the thickness of the polysilicon to the thickness of the gate electrode 112 is more than or equal to about 3. Perferably, the polysilcon layer is 300-1800 Å.

FIG. 1d illustrates wafer 100 after a second metal layer 150 has been deposited on the first conductive layer 140. The second metal layer 150 is preferably formed from an elemental metal, metal alloy, metal silicide, metal nitride, metal oxide, a combination thereof, or the like. More preferably, the second metal layer 150 is copper. Other suitable materials include titanium, titanium nitride, molybdenum, tantalum, aluminum, tantalum nitride, ruthenium, niobium, zirconium, tungsten, nickel, molybdenum nitride, cobalt, ruthenium oxide, magnesium, platinum, erbium, silver, palladium, iridium, or a combination thereof.

The second metal layer 150 may be formed, for example, by sputtering or CVD Preferably, the second metal layer 140 is deposited to a thickness sufficient to completely fill the contact hole 130.

FIG. 1e illustrates wafer 100 of FIG. 1d after a planarization process has been performed. One common method of planarizing wafer 100 is by chemical-mechanical polishing (CMP). Thereafter, standard processing techniques, such as depositing and patterning metal layers, forming vias, and the like, may be utilized to complete fabrication of the semiconductor device.

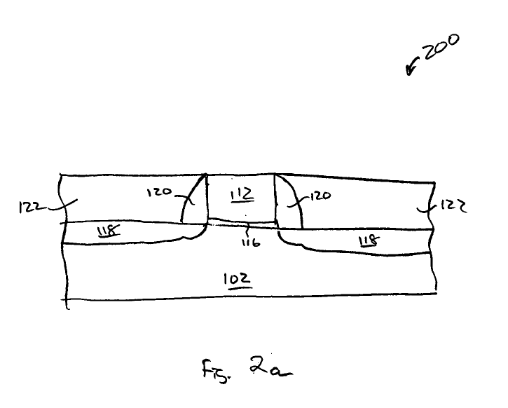

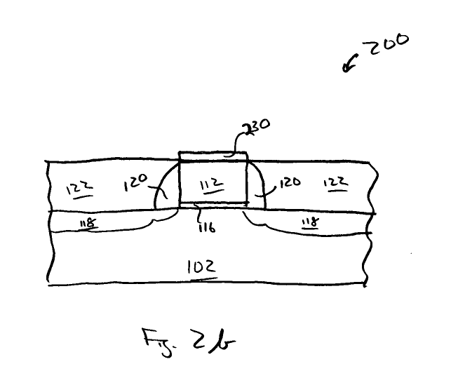

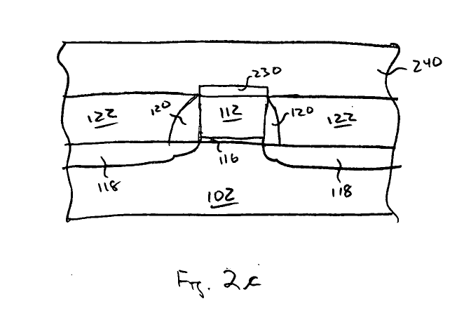

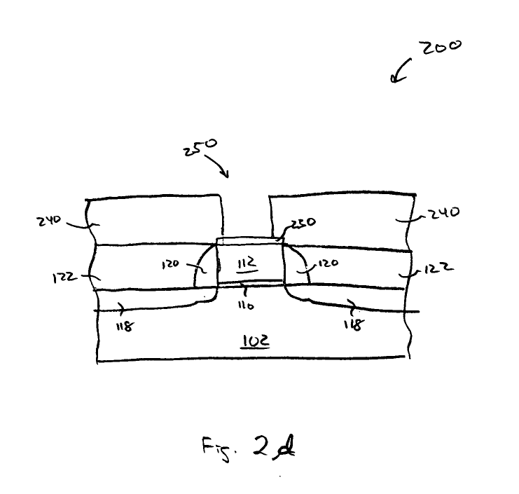

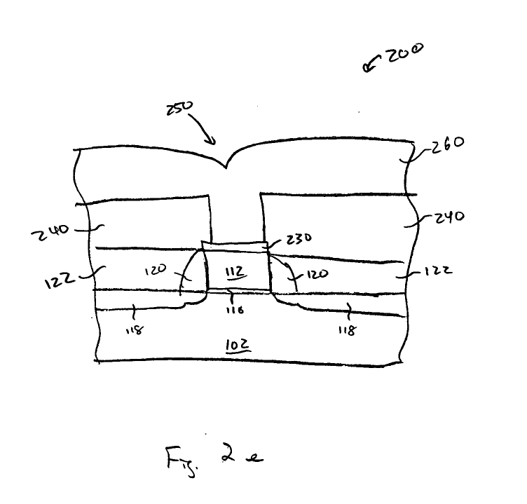

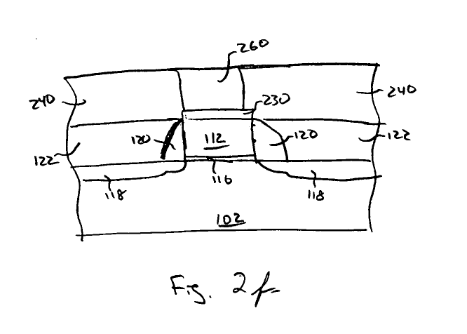

FIGS. 2a-2e illustrate cross-section views of a portion of a semiconductor wafer 200 during various steps of a second method embodiment of the present invention. The process begins in FIG. 2a, wherein a semiconductor wafer 200 having a transistor formed thereon is provided, wherein like reference numerals refer to like elements as discussed above with reference to FIG. 1a, except that the second ILD layer 124 has not been formed on wafer 200. The wafer 200 may be formed by standard processes as is known in the art.

FIG. 2b illustrates wafer 200 of FIG. 2a after a first conductive layer 230 has been formed and patterned. The first conductive layer 230 is preferably formed from an elemental metal, metal alloy, metal silicide, metal nitride, metal oxide, a combination thereof, or the like. Suitable materials include titanium, titanium nitride, molybdenum, tantalum, aluminum, tantalum nitride, ruthenium, niobium, zirconium, tungsten, nickel, molybdenum nitride, cobalt, ruthenium oxide, magnesium, platinum, copper, erbium, silver, palladium, iridium, or a combination thereof. More preferably, however, the first conductive layer 230 comprises titanium nitride, tantalum nitride, or the like. Furthermore, the first conductive layer 230 is preferably not the same type of metal as the gate electrode 112. In this manner, the first conductive layer 140 may be selected such that the first conductive layer 140 may act as an adhesion layer and a barrier layer between the gate electrode 112 and a second metal layer 150, which is discussed below with reference to FIG. 2d.

The first conductive layer 230 may be formed, for example, by sputtering or CVD. Preferably, the second metal layer 140 is 50-100 Å, but more preferably about 100 Å

Once formed, the first conductive layer 230 may be patterned by standard photolithography techniques. Generally, a photoresist material is deposited, masked, exposed, and developed to expose unwanted portions of the material first conductive layer 230, which is removed by a subsequent etching process. In the preferred embodiment in which the first conductive layer 230 is formed of titanium nitride, tantalum nitride, or the like, the etching process may be performed by an anisotropic dry etch process

In an alternative embodiment, the first conductive layer 140 may comprise a semiconductor material such as polysilicon, amorphous silicon, or the like, but preferably polysilicon. The polysilicon may be deposited doped or undoped. For example, the first conductive layer 240 may be formed by depositing undoped polysilicon by LPCVD. The polysilicon may be doped with other n-type dopants, such as nitrogen, phosphorous, arsenic, antimony, or the like, or other p-type dopants, such as boron, aluminum, gallium, indium, or the like. The polysilicon layer may also be deposited, for example, by furnace deposition of an in-situ doped polysilicon.

In this alternative embodiment, it is preferred that the thickness of the first conductive layer is such that the ratio of the thickness of the polysilicon to the thickness of the gate electrode 112 is less than or equal to about 3. Perferably, the polysilcon layer is 300-1800 Å.

FIG. 2c illustrates wafer 200 of FIG. 2b after a second ILD layer 240 has been formed. The second ILD layer 240 typically comprises silicon oxide formed, for example, by deposition techniques such as chemical vapor deposition (CVD). The second ILD layer 240 is preferably about 1000 Å to about 6000 Å in thickness, but more preferably about 4000 Å in thickness.

FIG. 2d illustrates wafer 200 of FIG. 2c after a contact hole 250 has been formed in the second ILD layer 240. The second ILD layer 240 is preferably patterned by photolithography techniques and etching as is known in the art. The etching process may be a wet or dry, anisotropic or isotropic, etch process, but preferably is an anisotropic dry etch process.

In this embodiment, the first conductive layer 230 may act as an etch stop layer when forming the contact hole 250. In other words, the etch process described above preferably has a high etch selectivity between the second ILD layer 240 and the first conductive layer 230 such that the second ILD layer 240 is etched at a higher rate than the first conductive layer 230. One skilled in the art will further appreciate that because an etch stop layer is utilized, the etching process does not damage the gate electrode 112, thereby providing more predictable and consistent operating characteristics.

FIG. 2e illustrates wafer 200 of FIG. 2d after a second metal layer 260 has been deposited on the first conductive layer 230. The second metal layer 260 is preferably formed from an elemental metal, metal alloy, metal silicide, metal nitride, metal oxide, a combination thereof, or the like. More preferably, the second metal layer 260 is copper. Other suitable materials include titanium, titanium nitride, molybdenum, tantalum, aluminum, tantalum nitride, ruthenium, niobium, zirconium, tungsten, nickel, molybdenum nitride, cobalt, ruthenium oxide, magnesium, platinum, erbium, silver, palladium, iridium, or a combination thereof.

The second metal layer 260 may be formed, for example, by sputtering or CVD. Preferably, the second metal layer 260 is deposited to a thickness sufficient to fill the contact hole 250. In one embodiment in which the contact hole 250 is about 4000 Å in thickness and about 90 Å in width, the second metal layer 260 is preferably about 10 Å to about 600 Å in thickness, but more preferably about 300 Å in thickness.

FIG. 2f illustrates wafer 100 of FIG. 2e after a planarization process has been formed. One common method of planarizing wafer 100 is by chemical-mechanical polishing (CMP) using a oxide slurry. Thereafter, standard processing techniques, such as depositing and patterning metal layers, forming vias, and the like, may be utilized to complete fabrication of the semiconductor device.

In the foregoing specification, the invention has been described with reference to specific embodiments. However, various modifications and changes can be made by one skilled in the art without departing from the scope of the present invention. Accordingly, the specification and figures are to be regarded in an illustrative rather than a restrictive sense, and all such modifications are intended to be included within the scope of the present invention. For example, while the present invention has been illustrated with reference to fabricating a transistor, it is understood that the present invention may be extended to fabricate multiple transistors or other semiconductor structures in which it would be advantageous to utilize metal portion to metal contact structure.

Although particular embodiments of the invention have been described in detail, it is understood that the invention is not limited correspondingly in scope, but includes all changes, modifications, and equivalents coming within the spirit and terms of the claims appended hereto. For example, differing types of materials and differing thicknesses may be, and the like. Accordingly, it is understood that this invention may be extended to other structures and materials, and thus, the specification and figures are to be regarded in an illustrative rather than a restrictive sense.

1. A semiconductor device comprising:
a semiconductor substrate having a transistor formed thereon, the transistor having a metal gate electrode;
an interlayer dielectric over the metal gate electrode; and
a contact hole formed through the interlayer dielectric to the metal gate electrode, wherein the contact hole is filled with a first metal layer and wherein a conductive layer is positioned between the first metal layer and the metal gate electrode.

2. The semiconductor device of claim 1, wherein a minimum feature size is less than or equal to about 65 nm.

3. The semiconductor device of claim 1, wherein the metal gate electrode is an elemental metal, a metal alloy, a metal nitride, a metal oxide, titanium, titanium nitride, molybdenum, tantalum, aluminum, tantalum nitride, ruthenium, niobium, zirconium, tungsten, nickel, molybdenum nitride, cobalt, ruthenium oxide, magnesium, platinum, copper, erbium, silver, palladium, iridium, or a combination thereof.

4. The semiconductor device of claim 1, wherein the conductive layer is polysilicon molybdenum, aluminum, ruthenium, niobium, zirconium, tungsten, nickel, molybdenum nitride, cobalt, ruthenium oxide, magnesium, platinum, copper, erbium, silver, palladium, iridium, titanium, titanium nitride, tantalum, aluminum, tantalum nitride, an elemental metal, a metal alloy, a metal silicide, a metal nitride, a metal oxide, or a combination thereof.

5. The semiconductor device of claim 1, further comprising a gate dielectric between the metal gate electrode and the semiconductor substrate.

6. The semiconductor device of claim 5, wherein said gate dielectric layer is transition metal oxide and has a dielectric constant less than or equal to about 50.

7. The semiconductor device of claim 5, wherein said gate dielectric has an EOT thickness less than or equal to about 50 Å.

8. The semiconductor device of claim 5, wherein said gate dielectric is a silicon-containing material, an oxygen-containing material, or a nitrogen-containing material.

9. The semiconductor device of claim 1, wherein the conductive layer is a barrier layer.

10. The semiconductor device of claim 1, wherein the conductive layer is an adhesion layer.

11. The semiconductor device of claim 1, wherein the conductive layer is larger than 5 Å in thickness.

12. The semiconductor device of claim 1, wherein the conductive layer is less than 500 Å in thickness.

13. The semiconductor device of claim 1, wherein the first metal layer is an elemental metal, a metal alloy, a metal silicide, a metal nitride, a metal oxide, molybdenum, aluminum, ruthenium, niobium, zirconium, tungsten, nickel, molybdenum nitride, cobalt, ruthenium oxide, magnesium, platinum, copper, erbium, silver, palladium, iridium, titanium, titanium nitride, tantalum, tantalum nitride or a combination thereof.

14. A method of forming a semiconductor device, the method comprising:
providing a substrate;
forming a gate dielectric on the substrate;
forming a metal gate electrode on the gate dielectric;
forming source/drain regions on the substrate adjacent to the metal gate electrode;
forming an interlayer dielectric on the metal gate electrode;
forming a contact hole in the interlayer dielectric such that at least a portion of the contact hole is above the metal gate electrode;
forming a conductive layer in the contact hole such that the conductive layer is in electrical contact with the metal gate electrode; and
forming a metal contact on the conductive layer in the contact hole.

15. The method of claim 14, wherein a minimum feature size is less than or equal to about 65 nm.

16. The method of claim 14, wherein the metal gate electrode is an elemental metal, a metal alloy, a metal nitride, a metal oxide, titanium, titanium nitride, molybdenum, tantalum, aluminum, tantalum nitride, ruthenium, niobium, zirconium, tungsten, nickel, molybdenum nitride, cobalt, ruthenium oxide, magnesium, platinum, copper, erbium, silver, palladium, iridium, or a combination thereof.

17. The method of claim 14, wherein the conductive layer is polysilicon, molybdenum, aluminum, ruthenium, niobium, zirconium, tungsten, nickel, molybdenum nitride, cobalt, ruthenium oxide, magnesium, platinum, copper, erbium, silver, palladium, iridium, titanium, titanium nitride, tantalum, tantalum nitride, an elemental metal, a metal alloy, a metal silicide, a metal nitride, a metal oxide, or a combination thereof.

18. The method of claim 17, wherein the gate dielectric is formed of a transition metal oxide and has a dielectric constant less than or equal to about 50.

19. The method of claim 14, wherein the gate dielectric has an EOT thickness less than or equal to about 50 Å.

20. The method of claim 14, wherein the gate dielectric is a silicon-containing material, an oxygen-containing material, or a nitrogen-containing material.

21. The method of claim 14, wherein the conductive layer is a barrier layer.

22. The method of claim 14, wherein the conductive layer is an adhesion layer.

23. The method of claim 14, wherein the conductive layer is about 5 to about 500 Å in thickness.

24. The method of claim 14, wherein the metal contact is an elemental metal, a metal alloy, a metal silicide, a metal nitride, a metal oxide, molybdenum, aluminum, ruthenium, niobium, zirconium, tungsten, nickel, molybdenum nitride, cobalt, ruthenium oxide, magnesium, platinum, copper, erbium, silver, palladium, iridium, titanium, titanium nitride, tantalum, tantalum nitride, or a combination thereof.

25. A method of forming a semiconductor device, the method comprising:
providing a substrate having a transistor formed thereon, the transistor having a metal gate;
providing a first conductive layer on the metal gate such that at least a portion of the first conductive layer is in electrical contact with the metal gate;
depositing an interlayer dielectric on the first conductive layer;
forming a contact hole in the interlayer dielectric such that the contact hole exposes at least a portion of the first conductive layer; and
forming a metal contact on the first conductive layer in the contact hole.

26. The method of claim 25, wherein structures formed on the substrate have a minimum feature size is less than or equal to about 65 nm.

27. The method of claim 25, wherein a dielectric layer is positioned between the metal gate and the substrate.

28. The method of claim 27, wherein the first conductive layer is an elemental metal, a metal alloy, a metal silicide, a metal nitride, a metal oxide, or a combination thereof.

29. The method of claim 28, wherein the dielectric layer is formed of a transition metal oxide and has a dielectric constant less than or equal to about 50.

30. The method of claim 27, wherein the dielectric layer has a EOT thickness less than or equal to about 50 Å.

31. The method of claim 27, wherein the dielectric layer is a silicon-containing material, an oxygen-containing material, or a nitrogen-containing material.

32. The method of claim 25, wherein the first conductive layer is a barrier layer.

33. The method of claim 25, wherein the first conductive layer is an adhesion layer.

34. The method of claim 25, wherein the first conductive layer is more than about 5 Å in thickness.

35. The method of claim 25, wherein the first conductive layer is less than 500 Å in thickness.

36. The method of claim 25, wherein the metal gate is an elemental metal, a metal alloy, a metal nitride, a metal oxide, molybdenum, aluminum, ruthenium, niobium, zirconium, tungsten, nickel, molybdenum nitride, cobalt, ruthenium oxide, magnesium, platinum, copper, erbium, silver, palladium, iridium, titanium, titanium nitride, tantalum, tantalum nitride, or a combination thereof.

37. The method of claim 25, wherein the metal contact is polysilicon, an elemental metal, a metal alloy, a metal nitride, a metal oxide, polysilicon, molybdenum, aluminum, ruthenium, niobium, zirconium, tungsten, nickel, molybdenum nitride, cobalt, ruthenium oxide, magnesium, platinum, copper, erbium, silver, palladium, iridium, titanium, titanium nitride, tantalum, tantalum nitride, or a combination thereof.
